(19) United States
(12) Patent Application Publication
(10) Pub. No.: US 2020/0287054 A1
(43) Pub. Date: Sep. 10, 2020

(54) SEMICONDUCTOR DEVICE AND METHOD FOR PRODUCING THE SAME

(71) Applicant: Sharp Kabushiki Kaisha, Sakai City (JP)

(72) Inventors: Masahiko SUZUKI, Sakai City (JP); Hajime IMAI, Sakai City (JP); Tetsuo KIKUCHI, Sakai City (JP); Yoshimasa CHIKAMA, Sakai City (JP); Setsuji NISHIMIYA, Sakai City (JP); Teruyuki UEDA, Sakai City (JP); Masamitsu YAMANAKA, Sakai City (JP); Kengo HARA, Sakai City (JP); Hitoshi TAKAHATA, Sakai City (JP); Tohru DAITOH, Sakai City (JP)

(21) Appl. No.: 16/808,463

(22) Filed: Mar. 4, 2020

Related U.S. Application Data
(60) Provisional application No. 62/815,406, filed on Mar. 8, 2019.

(51) Int. Cl. H01L 29/786; H01L 29/66; H01L 29/423

(52) U.S. Cl. CPC H01L 29/78693; H01L 29/42384; H01L 29/66742

(57) ABSTRACT

A semiconductor device includes a thin film transistor including a semiconductor layer, a gate electrode, a gate insulating layer positioned between the semiconductor layer and the gate electrode, and a source electrode and a drain electrode that are electrically connected to the semiconductor layer, wherein the semiconductor layer has a stacked layer structure including a first oxide semiconductor layer including In, Ga, Zn, and Sn, and a second oxide semiconductor layer including In, Ga, Zn, and Sn, having a lower mobility than the first oxide semiconductor layer, and disposed on the first oxide semiconductor layer so as to be in direct contact with the first oxide semiconductor layer, the first and the second oxide semiconductor layers are amorphous, and a Sn atomic ratio R1 relative to all metal elements in the first oxide semiconductor layer and a Sn atomic ratio R2 relative to all metal elements in the second oxide semiconductor layer satisfy 0.8×R1≤R2≤1.2×R1.

### TECHNICAL FIELD

The present invention relates to a semiconductor device formed from oxide semiconductors and a method for producing the semiconductor device.

### BACKGROUND ART

An active matrix substrate used for, for example, liquid crystal display apparatuses includes, for each pixel, a switching device such as a thin film transistor (Thin Film Transistor; hereafter, “TFT”). As such TFTs (hereafter, “pixel TFTs”), TFTs having an amorphous silicon film as the active layer (hereafter, “amorphous silicon TFTs”) and TFTs having a polycrystalline silicon film as the active layer (hereafter, “polycrystalline silicon TFTs”) have been widely used.

On the other hand, there is a known technique of providing a peripheral circuit such as a driving circuit on a substrate monolithically (in one piece). Such monolithic formation of the driving circuit provides a reduction in the width or size of the non-display region and a reduction in the costs due to simplification of the mounting step. In this Specification, a TFT constituting a peripheral circuit monolithically formed on an active matrix substrate will be referred to as “circuit TFT”.

As the material for the active layer of a TFT, instead of amorphous silicon or polycrystalline silicon, oxide semiconductor is used in some cases. Such a TFT is referred to as “oxide semiconductor TFT”. Known examples of the material for the active layer of an oxide semiconductor TFT include a ternary oxide (In—Ga—Zn—O-based semiconductor) including In (indium), Ga (gallium), and Zn (zinc), and a ternary oxide (In—Zn—Sn—O-based semiconductor) including In, Zn, and Sn (tin). Oxide semiconductors have higher mobility than amorphous silicon. For this reason, oxide semiconductor TFTs can operate faster than amorphous silicon TFTs. Thus, oxide semiconductor TFTs can be suitably used not only as pixel TFTs but also as circuit TFTs.

In recent years, in order to provide active matrix substrates that, for example, have higher definition and lower power consumption, and are driven at a higher frequency (for example, at 120 Hz), there has been a demand for a further increase in the channel mobility of oxide semiconductor TFTs. Thus, it has been proposed to use oxide semiconductor materials (hereafter, abbreviated as “high mobility materials”) that can have higher mobility than In—Ga—Zn—O-based semiconductors. For example, Patent Literature 1 discloses, as a high mobility material, a quaternary oxide (In—Ga—Zn—Sn—O-based semiconductor) including In, Ga, Zn, and Sn (tin).

### CITATION LIST

### Patent Literature

[PTL 1] Japanese Unexamined Patent Application Publication No. 2017-157813

### SUMMARY OF INVENTION

The inventor of the present invention performed studies and has found the following: the higher the mobility of an oxide semiconductor material, the higher the probability of deterioration caused by the ingress of, for example, water or hydrogen. For example, in the case of using the In—Ga—Zn—Sn—O-based semiconductor disclosed in PTL 1 for an oxide semiconductor layer, ingress of, for example, water or hydrogen into the oxide semiconductor layer causes a decrease in the resistance of the oxide semiconductor layer, which tends to cause the threshold voltage Vth of the oxide semiconductor TFT to shift to the negative side. This may result in an increase in the off-leak current, or occurrence of depletion (normally-on state). This may cause, in the case of using the oxide semiconductor TFT as a pixel TFT, bright pixel defect in which the pixel always remains at the maximum pixel value, or, in the case of using the oxide semiconductor TFT as a circuit TFT, malfunction of a circuit such as a gate driver circuit.

Thus, in the case of using the In—Ga—Zn—Sn—O-based semiconductor for the active layer of a TFT, it is difficult to achieve, with suppression of degradation of reliability, a high channel mobility.

Incidentally, in this Specification, the mobility of a channel region of the active layer (oxide semiconductor layer) of an oxide semiconductor TFT will be referred to as “channel mobility”, which is distinguished from the mobility of the oxide semiconductor material itself.

Under such circumstances, an embodiment of the present invention has been made. An object of the embodiment is to provide a semiconductor device including an oxide semiconductor TFT that can have, with ensured reliability, a high channel mobility.

This Specification discloses semiconductor devices and methods for producing a semiconductor device described in the following Items.

### [Item 1]

A semiconductor device including a substrate and a thin film transistor supported by the substrate,

wherein the thin film transistor includes a semiconductor layer, a gate electrode, a gate insulating layer positioned between the semiconductor layer and the gate electrode, and a source electrode and a drain electrode that are electrically connected to the semiconductor layer,

the semiconductor layer has a stacked layer structure including
a first oxide semiconductor layer including In, Ga, Zn, and Sn, and
a second oxide semiconductor layer including In, Ga, Zn, and Sn, having a lower mobility than the first oxide semiconductor layer, and being disposed on the first oxide semiconductor layer so as to be in direct contact with the first oxide semiconductor layer,

the first oxide semiconductor layer and the second oxide semiconductor layer are amorphous, and

a Sn atomic ratio R1 relative to all metal elements in the first oxide semiconductor layer and a Sn atomic ratio R2 relative to all metal elements in the second oxide semiconductor layer satisfy

0.8×R1≤R2≤1.2×R1.

### [Item 2]

The semiconductor device according to Item 1, wherein the Sn atomic ratio R1 in the first oxide semiconductor layer and the Sn atomic ratio R2 in the second oxide semiconductor layer are each 5% or more and 25% or less.

### [Item 3]

The semiconductor device according to Item 1 or 2, wherein an In atomic ratio relative to all metal elements in the first oxide semiconductor layer is higher than an In atomic ratio relative to all metal elements in the second oxide semiconductor layer.

### [Item 4]

The semiconductor device according to any one of Items 1 to 3, wherein,

in the first oxide semiconductor layer, a Ga atomic ratio is lower than an In atomic ratio relative to all metal elements, and,

in the second oxide semiconductor layer, a Ga atomic ratio is higher than an In atomic ratio relative to all metal elements.

### [Item 5]

The semiconductor device according to any one of Items 1 to 4, wherein, at a side surface of the semiconductor layer, a side surface of the first oxide semiconductor layer and a side surface of the second oxide semiconductor layer align in a thickness direction, and the side surface of the semiconductor layer has a non-stepped shape.

### [Item 6]

The semiconductor device according to any one of Items 1 to 5, wherein the first oxide semiconductor layer and the second oxide semiconductor layer each include an In—Ga—Zn—Sn—O-based semiconductor.

### [Item 7]

The semiconductor device according to Item 6, wherein, in the first oxide semiconductor layer, relative to all metal elements, an In atomic ratio is 20% or more and 45% or less, a Ga atomic ratio is 5% or more and 20% or less, a Zn atomic ratio is 30% or more and 60% or less, and a Sn atomic ratio is 5% or more and 25% or less.

### [Item 8]

The semiconductor device according to Item 6 or 7, wherein, in the second oxide semiconductor layer, relative to all metal elements, an In atomic ratio is 10% or more and 20% or less, a Ga atomic ratio is 25% or more and 45% or less, a Zn atomic ratio is 20% or more and 35% or less, and a Sn atomic ratio is 5% or more and 25% or less.

### [Item 9]

The semiconductor device according to any one of Items 1 to 8, wherein the gate electrode is positioned between the semiconductor layer and the substrate.

### [Item 10]

The semiconductor device according to Item 9, wherein the first oxide semiconductor layer has a thickness smaller than a thickness of the second oxide semiconductor layer.

### [Item 11]

The semiconductor device according to any one of Items 1 to 10, wherein the gate electrode is positioned on a side of the semiconductor layer, the side being opposite from the substrate.

### [Item 12]

A method for producing a semiconductor device including a substrate and a thin film transistor supported by the substrate, the thin film transistor including a semiconductor layer, a gate electrode, a gate insulating layer formed between the gate electrode and the semiconductor layer, and a source electrode and a drain electrode that are electrically connected to the semiconductor layer, the semiconductor layer having a stacked layer structure including a first oxide semiconductor layer and a second oxide semiconductor layer,

the production method including:
Step (A) of forming a first oxide semiconductor film including In, Ga, Zn, and Sn and being amorphous;
Step (B) of forming, on the first oxide semiconductor film, a second oxide semiconductor film including In, Ga, Zn, and Sn, having a lower mobility than the first oxide semiconductor film, and being amorphous; and
Step (C) of patterning stacked semiconductor films including the first oxide semiconductor film and the second oxide semiconductor film to form, respectively from the first oxide semiconductor film and the second oxide semiconductor film, the first oxide semiconductor layer and the second oxide semiconductor layer,

wherein a Sn atomic ratio R1 relative to all metal elements in the first oxide semiconductor layer and a Sn atomic ratio R2 relative to all metal elements in the second oxide semiconductor layer satisfy

0.8×R1≤R2≤1.2×R1.

### [Item 13]

The method for producing a semiconductor device according to Item 12, wherein,

in the Step (C), wet etching using a PAN-based etchant being a mixture of phosphoric acid, nitric acid, and acetic acid is performed to pattern the first oxide semiconductor film and the second oxide semiconductor film,

a side surface of the semiconductor layer includes a side surface of the first oxide semiconductor layer and a side surface of the second oxide semiconductor layer, and

the side surface of the semiconductor layer has a non-stepped shape.

An embodiment of the present invention provides a semiconductor device including an oxide semiconductor TFT that can have, with ensured reliability, a high channel mobility.

### BRIEF DESCRIPTION OF DRAWINGS

FIG. 1A is a schematic sectional view of a TFT 101 according to a first embodiment.

FIG. 1B is a schematic plan view of the TFT 101 according to the first embodiment.

FIG. 2 is a sectional view of another TFT example according to the first embodiment.

FIG. 3A is a step sectional view illustrating a method for producing the TFT 101.

FIG. 3B is a step sectional view illustrating a method for producing the TFT 101.

FIG. 3C is a step sectional view illustrating a method for producing the TFT 101.

FIG. 3D is a step sectional view illustrating a method for producing the TFT 101.

FIG. 4A illustrates XRD analysis results of Sample substrate 1 having a first oxide semiconductor film 71a.

FIG. 4B illustrates XRD analysis results of Sample substrate 1 having a second oxide semiconductor film 72a.

FIG. 5A illustrates a sectional SEM image of an Example TFT.

FIG. 5B illustrates a sectional SEM image of a Comparative Example TFT.

FIG. 6A illustrates measurement results of I-V characteristics of an Example TFT.

FIG. 6B illustrates measurement results of I-V characteristics of a Comparative Example TFT.

FIG. 7 is a schematic sectional view of a TFT 102 according to a second embodiment.

FIG. 8 is a schematic sectional view of a TFT 103 of a modification according to the second embodiment.

FIG. 9 is a schematic view illustrating an example of a planar structure of an active matrix substrate 1000.

FIG. 10A is a plan view of a single pixel region P of an active matrix substrate 1000.

FIG. 10B is a sectional view of a portion of the active matrix substrate 1000.

### DESCRIPTION OF EMBODIMENTS

The inventor of the present invention studied TFT structures including In—Ga—Zn—Sn—O-based semiconductors, which are high mobility materials, and has found the following findings.

As described above, In—Ga—Zn—Sn—O-based semiconductor materials tend to deteriorate due to, for example, ingress of water, hydrogen, or the like. Thus, the inventor of the present invention studied the following configuration: an active layer is formed so as to have a stacked layer structure including, on an In—Ga—Zn—Sn—O-based semiconductor layer (hereafter, referred to as “high mobility layer”), an oxide semiconductor layer having a low mobility (hereafter, referred to as “low mobility layer”), so that the low mobility layer suppresses ingress of, for example, water into the high mobility layer.

However, even when such a stacked layer structure is used as the active layer of a TFT, a high channel mobility expected from the material characteristics of the In—Ga—Zn—Sn—O-based semiconductor is not obtained in some cases. The reason for this is inferred as follows: the thermal process or the like may cause Sn in the high mobility layer to diffuse into the low mobility layer (such as an In—Ga—Zn—O-based semiconductor layer), which results in a problem of deviation of the composition ratio of the high mobility layer from the desired composition ratio (composition deviation).

Incidentally, the above-described case is an example in which the high mobility layer is an In—Ga—Zn—Sn—O-based semiconductor layer. However, in the cases of using oxide semiconductor layers including In, Ga, Zn, and Sn, similar problems inferentially occur.

Under such circumstances, the inventor of the present invention has found the following findings: as the low mobility layer, an oxide semiconductor layer (such as an In—Ga—Zn—Sn—O-based semiconductor layer) having a Sn content ratio substantially the same as that of the high mobility layer is used, to thereby suppress diffusion of Sn from the high mobility layer to the low mobility layer. As a result, the decrease in the channel mobility due to composition deviation of the high mobility layer (such as a decrease in the Sn ratio) can be suppressed. Thus, while deterioration of the high mobility layer due to, for example, water from the outside is suppressed to ensure reliability, an increase in the channel mobility is achieved. When the high mobility layer and the low mobility layer having substantially the same Sn content are both amorphous, they are etched to advantageously provide smooth tapering side surfaces of the oxide semiconductor layer. This is inferentially achieved because the low mobility layer and the high mobility layer are smoothly connected to each other at their interface, and do not cause crystal anisotropy in terms of etching rate.

### First Embodiment

Hereinafter, a semiconductor device according to a first embodiment will be described with reference to drawings. The semiconductor device according to this embodiment, which at least includes an oxide semiconductor TFT (hereafter, “TFT”), widely encompasses, for example, circuit substrates such as active matrix substrates, various display apparatuses, and electronic apparatuses. In this embodiment, the oxide semiconductor TFT has a bottom-gate structure.

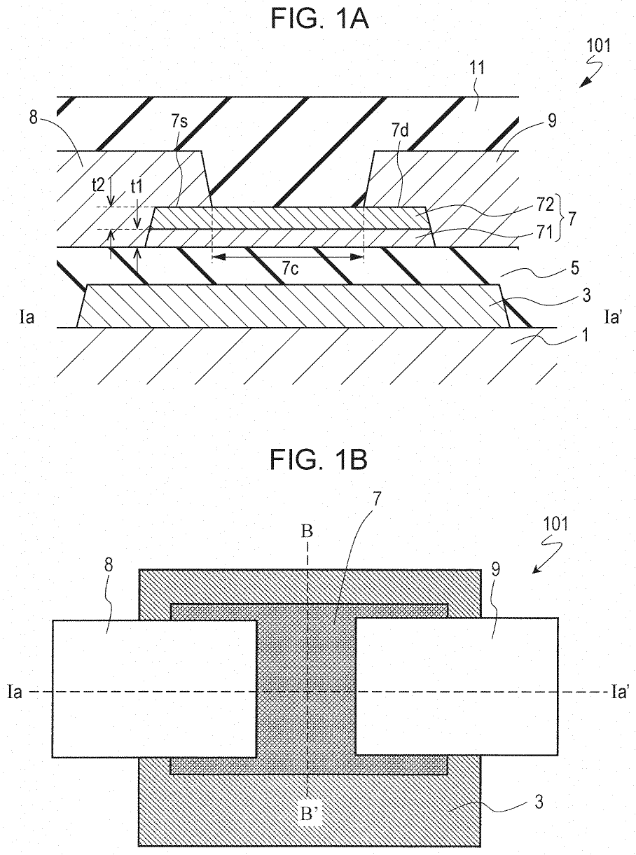

FIG. 1A and FIG. 1B are respectively a schematic sectional view and a plan view of an example of an oxide semiconductor TFT 101 in the semiconductor device according to this embodiment. FIG. 1A illustrates a sectional structure taken along line Ia-Ia′ in FIG. 1B.

A semiconductor device of this embodiment includes a substrate 1 and an oxide semiconductor TFT (hereafter, simply referred to as “TFT”) 101 supported by the substrate 1.

The TFT 101 includes a gate electrode 3 supported on the substrate 1, a semiconductor layer 7 including oxide semiconductors, a gate insulating layer 5 disposed between the semiconductor layer 7 and the gate electrode 3, and a source electrode 8 and a drain electrode 9 that are electrically connected to the semiconductor layer 7. The gate electrode 3 overlaps at least a portion of the semiconductor layer 7 with the gate insulating layer 5 therebetween. The TFT 101 may be covered with an inorganic insulating layer (passivation film) 11.

In this example, the TFT 101 is a channel-etched bottom-gate structure TFT. The gate electrode 3 is disposed between the semiconductor layer 7 and the substrate 1. The gate insulating layer 5 covers the gate electrode 3. The semiconductor layer 7 is disposed on the gate insulating layer 5 so as to overlap the gate electrode 3 with the gate insulating layer 5 therebetween. The source electrode 8 and the drain electrode 9 may each be disposed so as to be in contact with a portion of the upper surface of the semiconductor layer 7. In the semiconductor layer 7, such a portion in contact with the source electrode 8 is referred to as a source contact region 7s, and such a portion in contact with the drain electrode 9 is referred to as a drain contact region 7d. When viewed in a direction normal to the substrate 1, a region that is disposed between the source contact region 7s and the drain contact region 7d and overlaps the gate electrode 3 is a “channel region 7c”.

In this embodiment, the semiconductor layer 7 has a stacked layer structure including a first oxide semiconductor layer 71 and a second oxide semiconductor layer 72 disposed on the first oxide semiconductor layer 71 so as to be in direct contact with the first oxide semiconductor layer 71. The first oxide semiconductor layer 71 is a high mobility layer including In, Ga, Zn, and Sn. The second oxide semiconductor layer 72 is a low mobility layer including In, Ga, Zn, and Sn and having a lower mobility than the first oxide semiconductor layer 71. The first oxide semiconductor layer 71 and the second oxide semiconductor layer 72 are both amorphous.

A Sn atomic ratio (Sn ratio) R2 relative to all metal elements in the second oxide semiconductor layer 72 is substantially the same as a Sn atomic ratio (Sn ratio) R1 relative to all metal elements in the first oxide semiconductor layer 71. In this Specification, relative to all metal elements constituting an oxide semiconductor layer, atomic ratios (composition ratios) of In, Ga, Zn, and Sn are respectively referred to as “In ratio”, “Ga ratio”, “Zn ratio”, and “Sn ratio”. The phrase “a Sn ratio R2 in the second oxide semiconductor layer 72 is substantially the same as a Sn ratio R1 in the first oxide semiconductor layer 71” means that, for example, the Sn ratios R1 and R2 satisfy 0.8×R1≤R2≤1.2×R1 or may satisfy 0.9×R1≤R2≤1.1×R1. The Sn ratios R1 and R2 may be respectively average ratios in the first oxide semiconductor layer 71 and the second oxide semiconductor layer 72.

In the TFT 101 of this embodiment, of the semiconductor layer 7, the first oxide semiconductor layer 71 having a higher mobility can function as a layer through which carriers mainly flow (hereafter, “carrier-moving layer”). On the other hand, the second oxide semiconductor layer 72 can function as a protective layer that suppresses ingress of, for example, water or hydrogen from the outside into the first oxide semiconductor layer 71. When the TFT 101 has a channel-etched structure, the second oxide semiconductor layer 72 can function as a sacrificial layer that suppresses, in an etching step for source-drain separation, damage to the first oxide semiconductor layer 71.

As described above, in the case of forming, on an amorphous oxide semiconductor layer including In, Ga, Zn, and Sn (high mobility layer), a low mobility layer formed of another amorphous oxide semiconductor and having a lower mobility than the high mobility layer, a thermal process may cause Sn to diffuse from the high mobility layer to the low mobility layer, resulting in composition deviation (refer to Comparative Example described later). By contrast, in this embodiment, the first oxide semiconductor layer 71 serving as a high mobility layer and the second oxide semiconductor layer 72 serving as a low mobility layer include In, Ga, Zn, and Sn, and have substantially the same Sn ratio. Thus, diffusion of Sn in the thermal process is suppressed, to thereby suppress occurrence of composition deviation.

Thus, in this embodiment, the presence of the second oxide semiconductor layer 72 enables, while reliability is ensured, suppression of a decrease in the channel mobility due to diffusion of Sn from the first oxide semiconductor layer 71 into the second oxide semiconductor layer 72.

Furthermore, as described later, in the case of patterning, with the same etchant, the high mobility layer including In, Ga, Zn, and Sn and the low mobility layer formed of another amorphous oxide semiconductor (such as an In—Ga—Zn—O-based semiconductor layer), an etching selectivity ratio difference between the high mobility layer and the low mobility layer may result in formation of steps in the side surfaces of the active layer. As a result, good tapering shapes may not be obtained, or withstand stress voltage may decrease. By contrast, in this embodiment, the first oxide semiconductor layer 71 and the second oxide semiconductor layer 72 include the same metal elements In, Ga, Zn, and Sn, and are both amorphous; furthermore, the first oxide semiconductor layer 71 and the second oxide semiconductor layer 72 have substantially the same Sn ratio. Thus, the first oxide semiconductor layer 71 and the second oxide semiconductor layer 72 can be etched with the same etchant (such as a PAN-based etchant being a mixture of phosphoric acid, nitric acid, and acetic acid) so as to be patterned with substantially the same selectivity ratio, so that steps are less likely to be formed on the side surfaces of the semiconductor layer 7. Thus, the semiconductor layer 7 can be formed so as to have non-stepped side surfaces (tapering shapes). Thus, for example, the decrease in the withstand stress voltage due to steps on the side surfaces of the semiconductor layer 7 can be suppressed.

The first oxide semiconductor layer 71 may be the lowermost layer (layer closest to the substrate 1) of the semiconductor layer 7. The second oxide semiconductor layer 72 may be the uppermost layer of the semiconductor layer 7, and may have an upper surface in contact with the inorganic insulating layer 11.

Ratios of metal elements in the first oxide semiconductor layer 71 and the second oxide semiconductor layer 72 are not particularly limited, but are controlled such that the mobility of the first oxide semiconductor layer 71 is higher than the mobility of the second oxide semiconductor layer 72. For example, the In ratio of the first oxide semiconductor layer 71 may be higher than the In ratio of the second oxide semiconductor layer 72. With an increase in the In ratio, the electroconductivity increases, which results in an increase in the mobility.

On the other hand, an increase in the Ga ratio results in suppression of an increase in the number of oxygen defects that induce carriers in the oxide semiconductors. Thus, in the first oxide semiconductor layer 71, the In ratio may be higher than the Ga ratio. This enables a more effective increase in the mobility. On the other hand, in the second oxide semiconductor layer 72, the In ratio may be set to be lower than the Ga ratio, to thereby suppress the mobility.

In the first oxide semiconductor layer 71 and the second oxide semiconductor layer 72, the Sn ratios may be, for example, 5% or more. This enables a further increase in the mobility of the first oxide semiconductor layer 71. On the other hand, the Sn ratios may be, for example, 25% or less. This enables suppression of degradation of processibility due to crystalline Sn oxide.

In order to provide the first oxide semiconductor layer 71 and the second oxide semiconductor layer 72 as being amorphous, these layers may have Zn ratios of, for example, 20% or more and 40% or less. In this case, the oxygen content during film formation of oxide semiconductors may be, for example, 20% or less.

The first oxide semiconductor layer 71 and the second oxide semiconductor layer 72 may each include an In—Ga—Zn—Sn—O-based semiconductor. In the first oxide semiconductor layer 71, the In, Ga, Zn, and Sn ratio (atomic ratio) In:Ga:Zn:Sn may be, for example, 4:1:4:1. In the second oxide semiconductor layer 72, the In, Ga, Zn, and Sn ratio (atomic ratio) In:Ga:Zn:Sn may be, for example, 2:4:3:1.

The thickness t1 of the first oxide semiconductor layer 71 is not particularly limited, and may be, for example, 5 nm or more and 50 nm or less. In such a case of 5 nm or more, electrons mainly move through the first oxide semiconductor layer 71, compared with the second oxide semiconductor layer 72, to thereby achieve a more effective increase in the channel mobility. On the other hand, in such a case of 50 nm or less, the gate voltage can be used to achieve faster switching between On/Off of the TFT.

The second oxide semiconductor layer 72 may have a thickness t2 of, for example, 10 nm or more and 100 nm or less. In such a case of 10 nm or more, the layer can more effectively function as the protective layer for the first oxide semiconductor layer 71. This achieves a more effective reduction in the process damage to the first oxide semiconductor layer 71 during the source-drain separation step. On the other hand, when the thickness t2 is 100 nm or less, the second oxide semiconductor layer 72 causes a smaller resistance component, which enables suppression of a decrease in the channel mobility.

When the TFT 101 has a channel-etched structure, the thickness t2 may be, for example, 20 nm or more. The thickness t2 of the second oxide semiconductor layer 72 may be larger than the thickness t1 of the first oxide semiconductor layer 71. This enables, during the source-drain separation step, a more effective reduction in the etching damage to the first oxide semiconductor layer 71.

The first oxide semiconductor layer 71 and the second oxide semiconductor layer 72 may be monolayers. In each of the first oxide semiconductor layer 71 and the second oxide semiconductor layer 72, the Sn concentration profile in the thickness direction may be substantially flat.

The semiconductor layer 7 may further include, an oxide semiconductor layer other than the first oxide semiconductor layer 71 and the second oxide semiconductor layer 72. The other oxide semiconductor layer may include Sn in substantially the same ratio as in the first oxide semiconductor layer 71. This enables suppression of diffusion of Sn within the semiconductor layer 7, to thereby obtain desired TFT characteristics with more certainty. Incidentally, the other oxide semiconductor layer may be a layer that substantially does not include Sn; the other oxide semiconductor layer may have a Sn ratio more than 20% different from the Sn ratio R1 of the first oxide semiconductor layer 71.

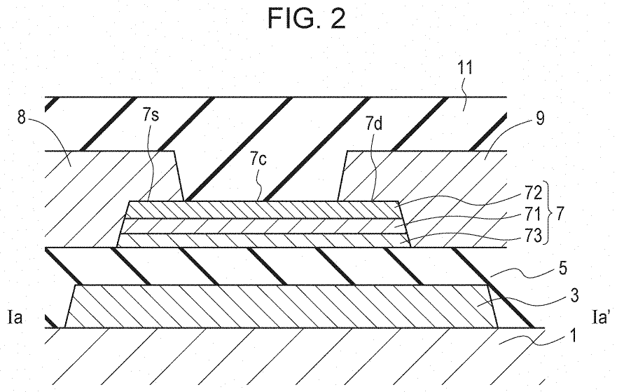

For example, as illustrated in FIG. 2 as an example, in the case where such another oxide semiconductor layer (third oxide semiconductor layer) 73 is disposed on the substrate 1-side of the first oxide semiconductor layer 71, the third oxide semiconductor layer 73 may include Sn in a ratio R3 substantially the same as in the first oxide semiconductor layer 71. Specifically, the Sn ratio R3 of the other oxide semiconductor layer may satisfy R1×0.8≤R3≤R1×1.2. The third oxide semiconductor layer 73 may have a lower mobility than the first oxide semiconductor layer 71. In this case, the first oxide semiconductor layer 71 functions as a carrier-moving layer, and the third oxide semiconductor layer 73 suppresses ingress of, for example, water from the substrate 1-side into the first oxide semiconductor layer 71.

### <Compositions of Layers of Semiconductor Layer 7>

Among constituent elements constituting the first oxide semiconductor layer 71 and the second oxide semiconductor layer 72, In can have an effect of increasing the electroconductivity of oxide semiconductors (increasing mobility); Ga can have an effect of controlling oxygen defects in oxide semiconductors, in other words, suppressing an increase in the number of oxygen defects inducing carriers; and Zn can have an effect of stabilizing the amorphous structure of oxide semiconductors. Sn is an element that has a relatively large ion radius and forms a conductive oxide SnO₂, and has an effect of increasing the mobility of oxide semiconductors. SnO₂ is insoluble in acids, has high chemical resistance, and has an effect of providing higher acid resistance.

First Oxide Semiconductor Layer 71

As described above, the first oxide semiconductor layer 71 includes In, Ga, Zn, and Sn. The In ratio may be higher than the Ga ratio, for example, may be higher than 2.0 times the Ga ratio ([In]/[Ga]>2.0). This provides an even higher mobility. The Zn ratio may be higher than 2.4 times the Sn ratio ([Zn]/[Sn]>2.4). This enables suppression of an increase in the conductivity due to crystalline Sn oxide. The first oxide semiconductor layer 71 may further include an element other than In, Ga, Zn, and Sn. The composition, formation method, characteristics, and the like of the first oxide semiconductor layer 71 are described in, for example, PTL 1. For reference, the entire contents disclosed in PTL 1 (Japanese Unexamined Patent Application Publication No. 2017-157813) are incorporated herein by reference.

The first oxide semiconductor layer 71 may include mainly an In—Ga—Zn—Sn—O-based semiconductor. In this case, the metal element ratios are not particularly limited; however, for example, the In ratio may be 20% or more and 45% or less, preferably 25% or more and 45% or less, the Ga ratio may be 5% or more and 20% or less, the Zn ratio may be 30% or more and 60% or less, and the Sn ratio may be 5% or more and 25% or less, preferably 5% or more and 15% or less.

The second oxide semiconductor layer 72, which at least includes In, Ga, Zn, and Sn, is not particularly limited in terms of composition ratio. In the second oxide semiconductor layer 72, the channel may not be formed, so that the In ratio may not be set high. For example, in the second oxide semiconductor layer 72, the In ratio may be lower than the Ga ratio. The In ratio may be equal to or lower than the Zn ratio, or may be lower than the Zn ratio.

The second oxide semiconductor layer 72 may include mainly an In—Ga—Zn—Sn—O-based semiconductor. In this case, the metal element ratios are not particularly limited; however, for example, the In ratio may be 10% or more and 20% or less, the Ga ratio may be 25% or more and 45% or less, the Zn ratio may be 20% or more and 35% or less, and the Sn ratio may be 5% or more and 25% or less, preferably 5% or more and 15% or less.

### <Method for Producing TFT 101>

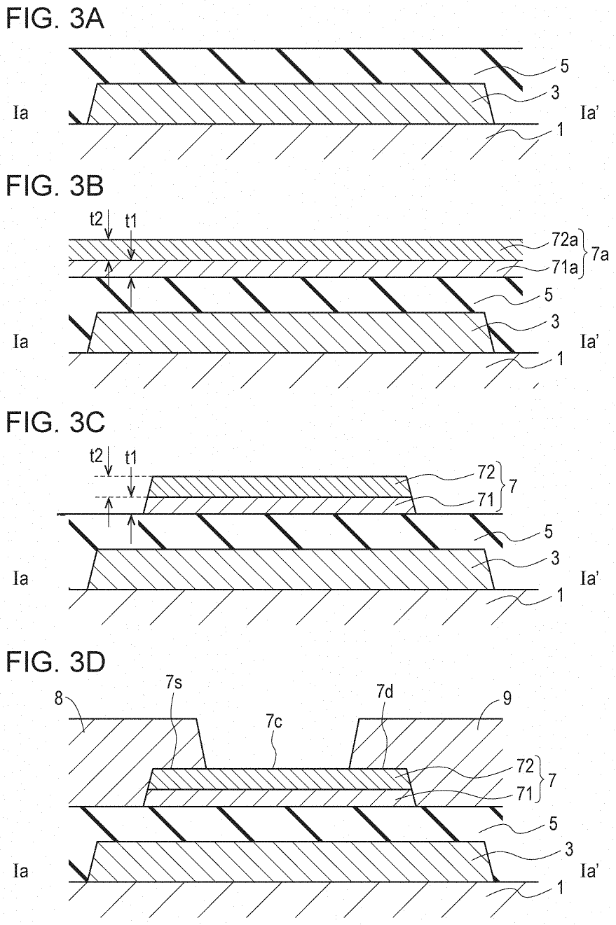

Hereinafter, an example of a method for producing the TFT 101 will be described with reference to FIG. 3A to FIG. 3D.

As illustrated in FIG. 3A, on a substrate 1, a gate electrode 3 is first formed. Subsequently, a gate insulating layer 5 is formed so as to cover the gate electrode 3.

Examples of the substrate 1 include glass substrates, silicon substrates, and heat-resistant plastic substrates (resin substrates).

The gate electrode 3 can be formed from a conductive film (hereafter, “gate-forming conductive film”) also used for a gate bus line GL described later. Here, on the substrate (such as a glass substrate) 1, a gate-forming conductive film (not shown, thickness: for example, 50 nm or more and 500 nm or less) is formed by a sputtering process, for example. Subsequently, the gate-forming conductive film is patterned, to thereby obtain the gate electrode 3. The gate-forming conductive film is, for example, a stacked layer film including a Ti film (thickness: 30 nm) or a Mo film as a lower layer, and a Cu film (thickness: 300 nm) as an upper layer. The material for the gate-forming conductive film is not particularly limited. A film including a metal such as aluminum (Al), tungsten (W), molybdenum (Mo), tantalum (Ta), chromium (Cr), titanium (Ti), or copper (Cu), an alloy of the foregoing, or a metal nitride of the foregoing can be appropriately employed.

The gate insulating layer 5 can be formed by a CVD process, for example. As the gate insulating layer 5, for example, a silicon oxide (SiO₂) layer, a silicon nitride (SiNx) layer, a silicon oxide nitride (SiOxNy; x>y) layer, or a silicon nitride oxide (SiNxOy; x>y) layer can be appropriately employed. The gate insulating layer 5 may have a stacked layer structure. For example, on the substrate side (as a lower layer), a silicon nitride layer, a silicon nitride oxide layer, or the like may be formed in order to prevent diffusion of impurities and the like from the substrate 1; as the overlying layer (upper layer), a silicon oxide layer, a silicon oxide nitride layer, or the like may be formed in order to ensure insulation. Here, a stacked layer film is employed that includes a SiO₂ film having a thickness of 50 nm as the upper layer, and a SiNx film having a thickness of 300 nm as the lower layer. In such a case of employing, as the uppermost layer (specifically, a layer in contact with the oxide semiconductor layer) of the gate insulating layer 5, an oxygen-containing insulating layer (for example, a layer of an oxide such as SiO₂), when the semiconductor layer 7 undergoes occurrence of oxygen vacancies, recovery from oxygen vacancies can be achieved with oxygen included in the oxide layer, to thereby achieve a reduction in the oxygen vacancies in the semiconductor layer 7.

Subsequently, as illustrated in FIG. 3B, on the gate insulating layer 5, for example, a sputtering process is performed to form, from the gate insulating layer 5-side, a first oxide semiconductor film 71a and a second oxide semiconductor film 72a, to obtain a stacked layer film 7a. The first oxide semiconductor film 71a is a film mainly including, for example, an In—Ga—Zn—Sn—O-based semiconductor (In:Ga:Zn:Sn=4:1:4:1). The second oxide semiconductor film 72a is a film mainly including, for example, an In—Ga—Zn—Sn—O-based semiconductor (In:Ga:Zn:Sn=2:4:3:1). The oxide semiconductor films 71a and 72a are each an amorphous oxide semiconductor film. The first oxide semiconductor film 71a may have a thickness t1 of, for example, 10 nm. The second oxide semiconductor film 72a may have a thickness t2 of, for example, 45 nm.

The first and second oxide semiconductor films 71a and 72a can be formed by, for example, a sputtering process using targets having the above-described compositions. The sputtering gas (atmosphere) may be a gas mixture of atoms of a rare gas such as argon and an oxidizing gas. Examples of the oxidizing gas include O₂, CO₂, O₃, H₂O, and N₂O. Here, a gas mixture including Ar gas and oxygen (O₂) gas is employed.

Subsequently, the stacked layer film 7a is subjected to an annealing treatment. Here, the heating treatment is performed in the air atmosphere at a temperature of 300° C. or more and 500° C. or less. The time for the heat treatment is, for example, 30 minutes or more and 2 hours or less.

Subsequently, as illustrated in FIG. 3C, the heat-treated stacked layer film 7a is patterned, to obtain a semiconductor layer 7. In this embodiment, the stacked layer film 7a is patterned by, for example, wet etching using a PAN-based etchant. This provides the semiconductor layer 7 including, from the gate insulating layer 5-side, a first oxide semiconductor layer 71 and a second oxide semiconductor layer 72 in this order. A side surface of the first oxide semiconductor layer 71 and a side surface of the second oxide semiconductor layer 72 align in the thickness direction. In addition, these side surfaces have substantially the same inclination angles (the inclination angles have a difference within ±10%, for example), so that the side surface of the semiconductor layer 7 has a non-stepped shape not having any step. Thus, the semiconductor layer 7 is formed so as to have a good tapering shape.

Incidentally, in the case of using the PAN-based etchant (liquid temperature: for example, 50° C.), the etching rate for the In—Ga—Zn—Sn—O-based semiconductor layer (In:Ga:Zn:Sn=4:1:4:1 or 2:4:3:1) is, for example, 0.08 nm/sec or more and 0.25 nm/sec or less, and the etching rate for the In—Ga—Zn—O-based semiconductor layer (In:Ga:Zn=1:1:1 or 1:3:6) is, for example, about 2.5 nm/sec.

Subsequently, as illustrated in FIG. 3D, a source electrode 8 and a drain electrode 9 are formed so as to be in contact with the upper surface of the semiconductor layer 7.

The source electrode 8 and the drain electrode 9 may have a monolayer structure or a stacked layer structure. The source electrode 8 and the drain electrode 9 can be formed from a conductive film (hereafter, “source-forming conductive film”) also used for a source bus line SL described later. As the source-forming conductive film, for example, a film including a metal such as aluminum (Al), tungsten (W), molybdenum (Mo), tantalum (Ta), chromium (Cr), titanium (Ti), or copper (Cu), an alloy of the foregoing, or a metal nitride of the foregoing may be appropriately employed.

In this example, as the source-forming conductive film, a stacked layer film is formed in which, from the semiconductor layer 7-side, a Ti film (thickness: 30 nm) and a Cu film (thickness: 300 nm) are stacked in this order. The source-forming conductive film is formed by, for example, a sputtering process. Subsequently, a resist mask is formed on the source-forming conductive film, and the source-forming conductive film is patterned. This provides a source electrode 8 and a drain electrode 9 (source-drain separation) that include the Ti film as the lower layer and the Cu film as the upper layer. Here, for example, a hydrogen peroxide-based etchant may be used to pattern the Cu film as the upper layer by wet etching, and subsequently the Ti film as the lower layer may be patterned by dry etching. Subsequently, the channel region of the semiconductor layer 7 may be subjected to an oxidization treatment such as a plasma treatment using N₂O gas. In this way, the TFT 101 is obtained.

Subsequently, an inorganic insulating layer 11 (not shown) is formed so as to be in contact with a channel region 7c of the TFT 101. The inorganic insulating layer 11 may be, for example, a silicon oxide (SiO₂) film, a silicon nitride (SiNx) film, a silicon oxide nitride (SiOxNy; x>y) film, or a silicon nitride oxide (SiNxOy; x>y) film. Here, as the inorganic insulating layer, a CVD process is performed to form a SiO₂ layer having a thickness of 300 nm, for example. The temperature at which the inorganic insulating layer is formed may be, for example, 200° C. or more and 450° C. or less. On the inorganic insulating layer 11, an organic insulating layer (not shown) may be formed. As the organic insulating layer, for example, a positive photosensitive resin film having a thickness of 2000 nm may be formed.

Incidentally, in the above-described method, the source-forming conductive film employed is a stacked layer film including a Ti film as the lower layer; alternatively, a stacked layer film including a Mo film as the lower layer may be employed. For example, as the source-forming conductive film, a stacked layer film may be formed by a sputtering process in which two layers that are, from the semiconductor layer 7-side, a Mo film (thickness: 30 nm) and a Cu film (thickness: 300 nm) are stacked in this order. In this case, wet etching using a hydrogen peroxide-based etchant may be performed to pattern both of the Cu film and the Mo film.

The TFT 101 illustrated has a top contact structure in which the source and drain electrodes are in contact with the upper surface of the semiconductor layer; alternatively, the TFT 101 may have a bottom contact structure in which the source and drain electrodes are in contact with the lower surface of the semiconductor layer.

The configuration of the bottom-gate TFT is also not limited to the above-described configuration. FIG. 1 illustrates, as an example, the bottom-gate TFT having the channel-etched structure. Alternatively, the TFT of this embodiment may be provided as a TFT (etch-stop TFT) including an etch stop layer (protective insulating layer) on the channel region. In the etch-stop TFT, the lower surfaces of the channel-side ends of the source and drain electrodes are positioned, for example, on the etch stop layer. The etch-stop TFT is formed in the following manner, for example: an etch stop layer is formed so as to cover a portion (to be a channel region) of the oxide semiconductor layer; subsequently, on the oxide semiconductor layer and the etch stop layer, a conductive film for the source and drain electrodes is formed, and source-drain separation is performed.

### <Analysis Results of Oxide Semiconductor Film>

Whether or not an oxide semiconductor film is provided in a crystalline state or in an amorphous state can be controlled by controlling the composition and film-formation conditions. In the In—Ga—Zn—Sn—O-based semiconductor, for example, by increasing the Zn ratio (for example, 20% or more, preferably 30% or more), an amorphous film is obtained.

The inventor of the present invention performed the following analysis in order to examine the states of the first oxide semiconductor layer 71 and the second oxide semiconductor layer 72.

Sample substrates 1 and 2 having a monolayer semiconductor film were first produced. The Sample substrate 1 was produced by forming, on a glass substrate, a first oxide semiconductor film 71a by a sputtering process. As the first oxide semiconductor film 71a, an In—Ga—Zn—Sn—O-based semiconductor film satisfying In:Ga:Zn:Sn=4:1:4:1 (thickness: 100 nm) was formed. Similarly, the Sample substrate 2 was produced by forming a second oxide semiconductor film 72a on a glass substrate. As the second oxide semiconductor film 72a, an In—Ga—Zn—Sn—O-based semiconductor film satisfying In:Ga:Zn:Sn=2:4:3:1 (thickness: 100 nm) was formed.

Incidentally, the above-described composition ratios of the In—Ga—Zn—O-based semiconductor films correspond to the compositions of targets used in the sputtering processes. However, deviations (for example, ±20% or less) may occur in the processes.

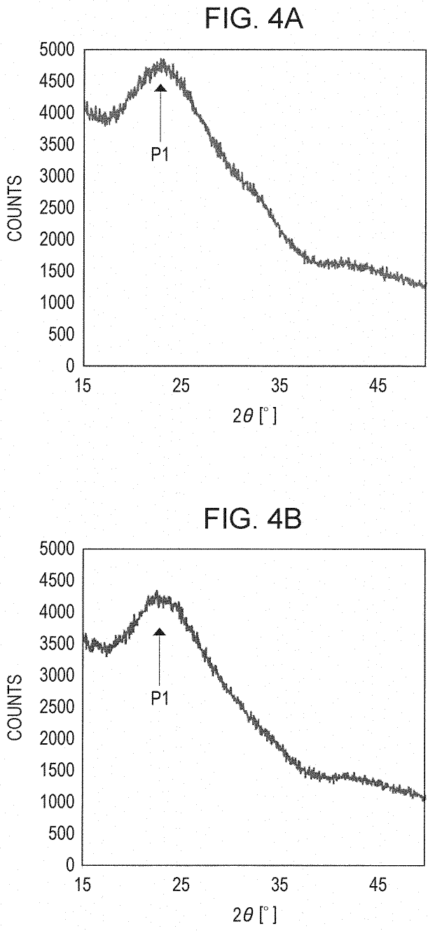

Subsequently, the obtained Sample substrates were analyzed by X-ray diffractometry (XRD). The X-ray diffraction patterns of Sample substrates 1 and 2 are respectively illustrated in FIG. 4A and FIG. 4B.

The X-ray diffraction patterns of Sample substrates 1 and 2 each have a broad peak P1 at 2θ=20 to 25°. This peak is inferentially attributable to the glass substrate. When such an oxide semiconductor film is crystalline, in addition to the peak P1 attributable to the glass substrate, a crystalline peak is formed at or near 2θ=30°, for example. However, each of the X-ray diffraction patterns of Sample substrates does not have crystalline peaks other than peak P1. This has demonstrated that both of the oxide semiconductor films 71a and 72a on Sample substrates 1 and 2 are amorphous.

### Example and Comparative Example

The inventor of the present invention produced TFTs of Example and Comparative Example, and evaluated their TFT characteristics.

The above-described method was first performed with reference to FIG. 3A to FIG. 3D to produce Example TFT. In Example, on a gate insulating layer, an In—Ga—Zn—Sn—O-based semiconductor film satisfying In:Ga:Zn:Sn=4:1:4:1 (thickness: 10 nm), and an In—Ga—Zn—Sn—O-based semiconductor film satisfying In:Ga:Zn:Sn=2:4:3:1 (thickness: 45 nm) were formed in this order, and a PAN-based etchant was used to pattern these semiconductor films. This formed a semiconductor layer 7 including, as the lower layer, an In—Ga—Zn—Sn—O-based semiconductor layer satisfying In:Ga:Zn:Sn=4:1:4:1 (first oxide semiconductor layer 71), and, as the upper layer, an In—Ga—Zn—Sn—O-based semiconductor layer satisfying In:Ga:Zn:Sn=2:4:3:1 (second oxide semiconductor layer 72).

In addition, for comparison, a method similar to that of Example was performed to produce Comparative Example TFT. Comparative Example TFT is different from Example TFT in that, as the upper layer of the semiconductor layer 7, an In—Ga—Zn—O-based semiconductor layer substantially not including Sn was formed. Specifically, on a gate insulating layer, an In—Ga—Zn—Sn—O-based semiconductor film satisfying In:Ga:Zn:Sn=4:1:4:1 (thickness: 10 nm), and an In—Ga—Zn—O-based semiconductor film satisfying In:Ga:Zn=1:3:6 (thickness: 45 nm) were formed in this order, and a PAN-based etchant was used to pattern the semiconductor films. This formed a semiconductor layer 7 including the In—Ga—Zn—Sn—O-based semiconductor layer (first oxide semiconductor layer 71) as the lower layer, and the In—Ga—Zn—O-based semiconductor layer (second oxide semiconductor layer 720) as the upper layer.

TABLE 1

| | Lower layer of semiconductor layer 7 | | Upper layer of semiconductor layer 7 | |
|---|---|---|---|---|
| | Composition | Thickness | Composition | Thickness |
| Example | In—Ga—Zn—Sn—O | 10 nm | In—Ga—Zn—Sn—O | 45 nm |
| | | | In:Ga:Zn:Sn = 2:4:3:1 | |
| Comparative | In:Ga:Zn:Sn = 4:1:4:1 | | In—Ga—Zn—O | 45 nm |
| Example | | | In:Ga:Zn = 1:3:6 | |

### Observation of SEM Sections

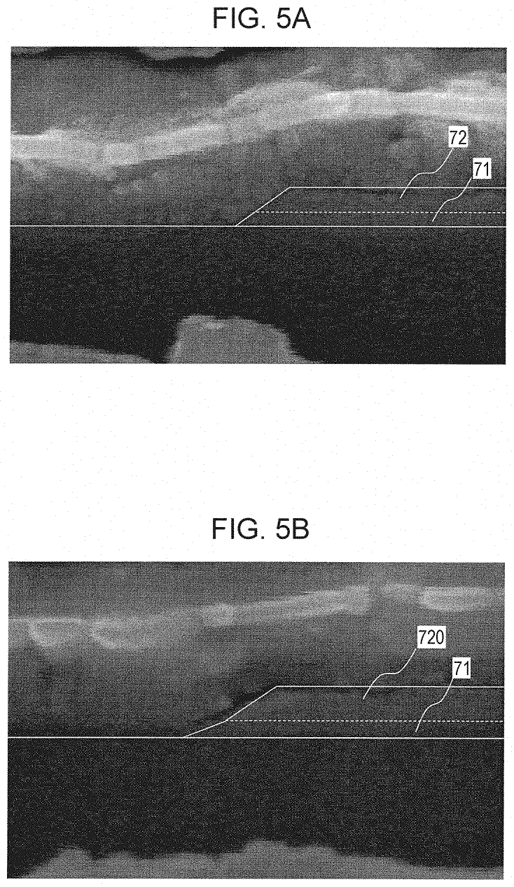

FIG. 5A and FIG. 5B illustrate sectional SEM images of the semiconductor layers 7 of Example and Comparative Example TFTs. To aid understanding, the semiconductor layers 7 are contoured with white lines.

As is clear from FIG. 5A, in Example, at the side surface of the semiconductor layer 7, the side surfaces of the first oxide semiconductor layer 71 and the second oxide semiconductor layer 72 align in the thickness direction. The side surface of the semiconductor layer 7 does not have any step (non-stepped shape), and the semiconductor layer 7 has a smooth tapering shape. In the patterning step for the semiconductor layer 7, the first oxide semiconductor layer 71 and the second oxide semiconductor layer 72 have substantially the same etching rate. The side surfaces of the first oxide semiconductor layer 71 and the second oxide semiconductor layer 72 have substantially the same inclination angle such as 30° or more and 50° or less (here, about 40°).

By contrast, as is clear from FIG. 5B, in Comparative Example, the inclination angle of the side surface of the Sn-containing first oxide semiconductor layer 71 (inclination angle of the side surface relative to the lower surface of the first oxide semiconductor layer 71) is smaller than the inclination angle of the side surface of the second oxide semiconductor layer (In—Ga—Zn—O-based semiconductor layer) 720 serving as the upper layer. Thus, the side surfaces of the first oxide semiconductor layer 71 and the second oxide semiconductor layer 720 form a step. Such a structure is inferentially formed because, in the patterning step for the semiconductor layer 7, the etching rate for the first oxide semiconductor layer 71 is lower than (for example, 1/10 or less of) the etching rate for the In—Ga—Zn—O-based semiconductor layer 720. The side surface of the first oxide semiconductor layer 71 has an inclination angle of less than 20°, for example. The side surface of the In—Ga—Zn—O-based semiconductor layer 720 has an inclination angle of, for example, 30° or more and 80° or less (here, about 30°).

### Measurement of I-V Characteristics

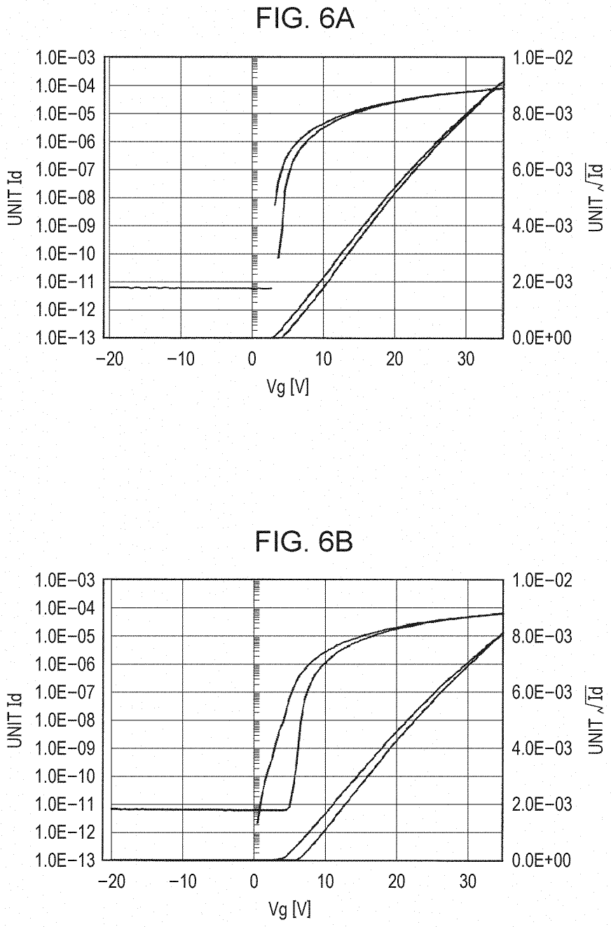

FIG. 6A and FIG. 6B are graphs illustrating measurement results of I-V characteristics of Example and Comparative Example TFTs. These graphs illustrate measurement results obtained while gate voltage Vg was changed from the negative side to the positive side, and measurement results obtained while gate voltage Vg was changed from the positive side to the negative side.

The measurement results have revealed that Example TFT has an about 30% higher channel mobility than Comparative Example TFT. The probable reason for this is as follows. In Comparative Example TFT, Sn diffused from the first oxide semiconductor layer 71 to the second oxide semiconductor layer (In—Ga—Zn—O-based semiconductor layer not containing Sn) 720, so that the Sn ratio in the first oxide semiconductor layer 71 decreased, which resulted in composition deviation and a decrease in the mobility of the first oxide semiconductor layer 71. By contrast, in Example TFT, the first oxide semiconductor layer 71 and the second oxide semiconductor layer 72 have substantially the same Sn ratio, so that diffusion of Sn is suppressed. This inferentially resulted in, in the first oxide semiconductor layer 71, suppression of the decrease in the mobility due to diffusion of Sn.

### Second Embodiment

A semiconductor device according to a second embodiment includes a substrate 1 and a top-gate structure TFT supported by the substrate 1. In the top-gate structure TFT, the gate electrode is disposed on the semiconductor layer (on a side of the semiconductor layer, the side being opposite from the substrate).

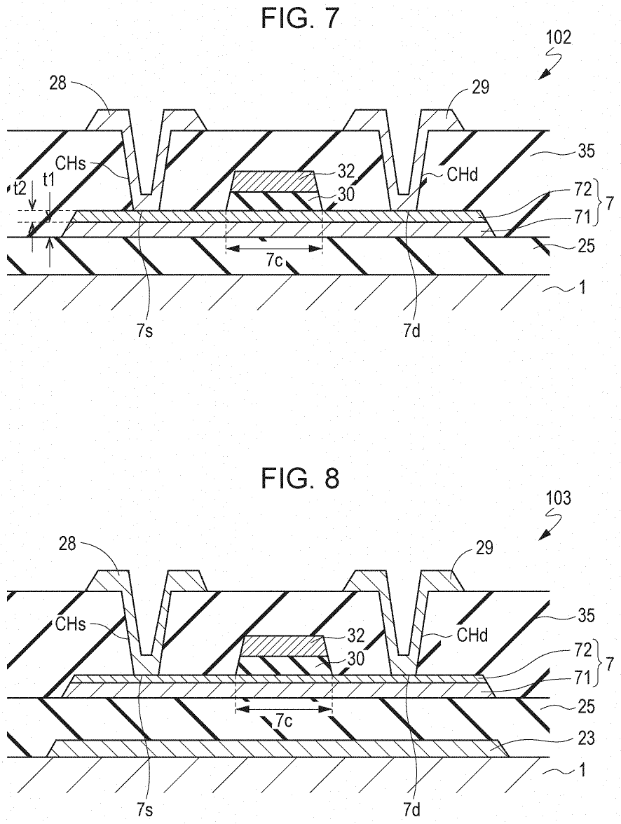

FIG. 7 is a sectional view of a TFT 102 according to this embodiment.

The TFT 102 includes a semiconductor layer 7, a gate insulating layer 30, a gate electrode 32, a source electrode 28, and a drain electrode 29. The gate electrode 32 is disposed on the semiconductor layer 7 with the gate insulating layer 30 therebetween. The gate electrode 32 is disposed so as to overlap, when viewed in a direction normal to the substrate 1, the channel region 7c of the semiconductor layer 7.

The semiconductor layer 7 is formed on the substrate 1. The semiconductor layer 7 may be disposed on a lower insulating layer 25 formed on the substrate 1.

The semiconductor layer 7 has a stacked layer structure similar to that of the semiconductor layer 7 described in the above embodiment. Specifically, the semiconductor layer 7 includes a first oxide semiconductor layer 71, and a second oxide semiconductor layer 72 disposed on the first oxide semiconductor layer 71. The semiconductor layer 7 may have non-stepped side surfaces. The second oxide semiconductor layer 72 may be in contact with the gate insulating layer 30. As described above with reference to FIG. 2, the stacked layer structure of the semiconductor layer 7 may further include, in addition to the first oxide semiconductor layer 71 and the second oxide semiconductor layer 72, another oxide semiconductor layer.

The first oxide semiconductor layer 71 and the second oxide semiconductor layer 72 may have thicknesses and composition ratios similar to those of the above-described embodiment. However, unlike the channel-etched structure TFT, in this embodiment, the second oxide semiconductor layer 72 does not necessarily have an increased thickness for suppressing etching damage to the first oxide semiconductor layer 71 in the source-drain separation step. Thus, the second oxide semiconductor layer 72 may have a thickness smaller than the thickness of the first oxide semiconductor layer 71, or may have a thickness equal to or smaller than the thickness of the first oxide semiconductor layer 71. A decrease in the thickness of the second oxide semiconductor layer 72 enables suppression of an increase in the resistance of the semiconductor layer 7. The second oxide semiconductor layer 72 may have a thickness of, for example, 5 nm or more and less than 15 nm.

The gate insulating layer 30 is disposed on a portion of the semiconductor layer 7. The gate insulating layer 30 may be formed only in a region overlapping the gate electrode 32. The gate electrode 32 is disposed on the gate insulating layer 30. The gate electrode 32 faces the semiconductor layer 7 with the gate insulating layer 30 therebetween.

The semiconductor layer 7, the gate insulating layer 30, and the gate electrode 32 are covered with an interlayer insulating layer 35. The source electrode 28 is disposed on the interlayer insulating layer 35 so as to be connected through a contact hole CHs formed in the interlayer insulating layer 35, to the source contact region 7s of the semiconductor layer 7. The drain electrode 29 is disposed on the interlayer insulating layer 35 so as to be connected through a contact hole CHd formed in the interlayer insulating layer 35, to the drain contact region 7d of the semiconductor layer 7.

Also in this embodiment, the second oxide semiconductor layer 72 is disposed on the first oxide semiconductor layer 71 functioning as a carrier-moving layer, to thereby suppress, for example, ingress of water into the first oxide semiconductor layer 71, which results in suppression of deterioration of TFT characteristics. The second oxide semiconductor layer 72 and the first oxide semiconductor layer 71 include In, Ga, Zn, and Sn and have substantially the same Sn ratio, which achieves suppression of diffusion of Sn between the first oxide semiconductor layer 71 and the second oxide semiconductor layer 72. This enables suppression of the decrease in the mobility due to diffusion of Sn.

### <Method for Producing TFT 102>

The TFT 102 can be formed in the following manner, for example. On an insulating layer (for example, a SiO₂ layer) 25, a method similar to that for the semiconductor layer 7 of the TFT 101 is performed to form a semiconductor layer 7. A first oxide semiconductor layer 71 may have a thickness of, for example, 30 nm. A second oxide semiconductor layer 72 may have a thickness of, for example, 10 nm.

Subsequently, a gate insulating film and an upper gate-forming conductive film are formed so as to cover the semiconductor layer 7. As the gate insulating film, for example, a silicon oxide (SiO₂) layer, a silicon nitride (SiNx) layer, a silicon oxide nitride (SiOxNy; x>y) layer, a silicon nitride oxide (SiNxOy; x>y) layer, an aluminum oxide layer, or a tantalum oxide layer may be appropriately employed. Here, as the gate insulating film, a silicon oxide (SiOx) layer (thickness: 80 nm or more and 250 nm or less, for example, 150 nm) is formed by a CVD process. As the upper gate-forming conductive film, a conductive film similar to the gate electrode 3 of the TFT 101 may be employed. Here, as the upper gate-forming conductive film, a stacked layer film including a Ti film as a lower layer and a Cu film as an upper layer is formed by a sputtering process.

Subsequently, the upper gate-forming conductive film and the gate insulating film are etched to obtain a gate electrode 32 and a gate insulating layer 30. Here, on the upper gate-forming conductive film, a resist mask is formed; through the resist mask, the upper gate-forming conductive film and the gate insulating film may be simultaneously etched. Alternatively, through the resist mask, the upper gate-forming conductive film may be patterned to form the gate electrode 32; subsequently, through the same resist mask or the gate electrode 32 serving as a mask, the gate insulating film may be patterned. In this way, portions of the gate insulating film not covered with the gate electrode 32 are removed.

Subsequently, from above the gate electrode 32, the whole surface of the substrate 1 may be subjected to a plasma treatment. This plasma treatment causes a decrease in the resistance of only regions of the semiconductor layer 7 that are not covered with the gate electrode 32.

Subsequently, an interlayer insulating layer 35 (thickness: for example, 100 nm or more and 500 nm or less) is formed so as to cover the semiconductor layer 7, the gate insulating layer 30, and the gate electrode 32. As the interlayer insulating layer 35, a silicon oxide film, a silicon nitride film, a silicon oxide nitride film, or a silicon nitride oxide film may be formed as a monolayer or a stacked layer. Here, as the interlayer insulating layer 35, SiNx (thickness: 100 nm) and a SiO₂ film (thickness: 300 nm) are continuously formed by a CVD process.

Incidentally, after the gate electrode 32 and the gate insulating layer 30 are patterned, an insulating film (for example, a film of a nitride such as SiNx) for reducing oxide semiconductor may be formed so as to be in contact with a portion of the upper surface of the semiconductor layer 7, the portion being exposed without being covered with the gate electrode 32. As a result, the exposed portion of the semiconductor layer 7 is reduced, to thereby have a decreased resistance (self-alignment structure). In this case, the above-described plasma treatment may be omitted.

Subsequently, in the interlayer insulating layer 35, contact holes CHs and CHd through which portions of the semiconductor layer 7 are exposed are formed. Subsequently, on the interlayer insulating layer 35 and within the contact holes CHs and CHd, a source-wiring-forming conductive film is formed. Here, a source-wiring-forming conductive film similar to that of the TFT 101 (a stacked layer film including a Ti film as a lower layer and an Al film as an upper layer) is employed. Subsequently, the source-wiring-forming conductive film is patterned, to obtain a source electrode 28 and a drain electrode 29. In this way, the TFT 102 is produced.

### <Modification>

FIG. 8 is a sectional view of another example, a TFT 103 according to this embodiment.

The TFT 103 is different from the TFT 102 in FIG. 7 in that it has a double gate (also referred to as dual gate) structure in which a lower electrode 23 is disposed between the substrate 1 and the lower insulating layer 25.

The lower electrode 23 is disposed so as to overlap, when viewed in a direction normal to the substrate 1, at least the channel region 7c. The lower electrode 23 may be a metal layer. In this case, the lower electrode 23 can also function as a light-shielding layer for the TFT 106. For example, the lower electrode 23 may be formed from a conductive film also used for forming the gate bus line GL (FIG. 1).

The lower electrode 23 may be grounded. This ensures the stability of characteristics of the TFT 103. The lower electrode 23 may be electrically connected to the source electrode 28. Alternatively, the lower electrode 23 may be electrically connected to the gate electrode 32 (or the gate bus line) so as to be at the same potential as in the gate electrode 32. The semiconductor layer 7 has, on its substrate 1-side, the first oxide semiconductor layer 71 serving as a carrier-moving layer. Thus, when, also on the substrate 1-side of the semiconductor layer 7, the lower electrode 23 functioning as a gate electrode is disposed, an increase in the on-state current is more effectively achieved.

### (Active Matrix Substrate)

The first and second embodiments are applicable to, for example, active matrix substrates of display apparatuses. At least a part of a plurality of TFTs disposed in such an active matrix substrate is the TFT according to such an embodiment. For example, as a pixel TFT disposed in each pixel and/or a TFT (circuit TFT) constituting a monolithic driver, the above-described TFT 101 is applicable.

Hereinafter, the configuration of such an active matrix substrate will be described with reference to a drawing.

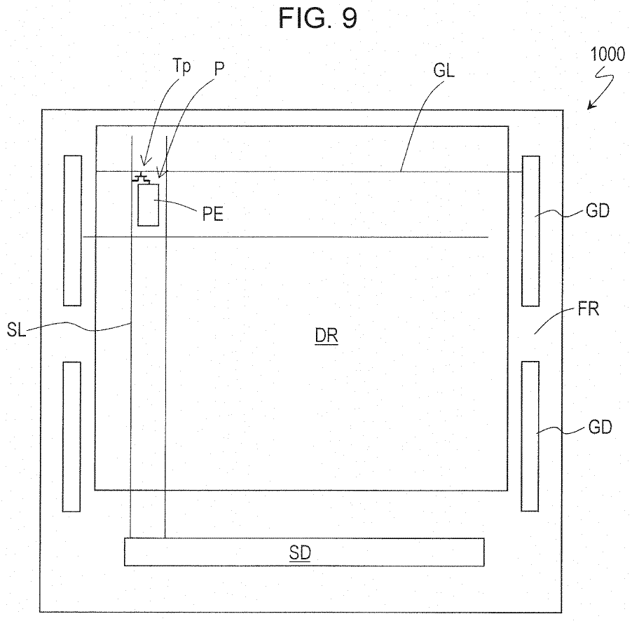

FIG. 9 is a schematic view of an example of a planar structure of an active matrix substrate 1000 according to this embodiment.

The active matrix substrate 1000 includes a display region DR and a region (a non-display region or a frame region) FR other than the display region DR. The display region DR is constituted by pixel regions P arranged in matrix. The pixel regions P are regions corresponding to pixels of the display apparatus, and may be simply referred to as “pixels”. Each pixel region P includes a thin film transistor Tp as a pixel TFT and a pixel electrode PE. In the case of applying the active matrix substrate 1000 to a display apparatus of a horizontal electric field mode such as an FFS (Fringe Field Switching) mode, the active matrix substrate 1000 is provided such that a common electrode (not shown) is disposed so as to face pixel electrodes PE with an insulating layer (dielectric layer) therebetween.

The non-display region FR is a region disposed around the display region DR and not contributing to displaying. The non-display region FR includes, for example, a terminal-formation region in which terminals are formed, and a driving circuit formation region in which driving circuits are provided in one piece (monolithically). In the driving circuit formation region, for example, gate drivers GD and a test circuit (not shown) are monolithically provided. A source driver SD is mounted on, for example, the active matrix substrate 1000. In the display region DR, a plurality of gate bus lines GL extending in the column direction and a plurality of source bus lines SL extending in the row direction are formed. Each pixel is defined by, for example, gate bus lines GL and source bus lines SL. The gate bus lines GL are connected to corresponding terminals of the gate drivers GD. The source bus lines SL are connected to corresponding terminals of the source driver SD mounted on the active matrix substrate 1000.

### Configuration of Pixel Region P

Hereinafter, the configuration of each pixel region P in the active matrix substrate 1000 will be described. The following are descriptions with reference to, as an example, an active matrix substrate applied to an LCD panel of an FFS mode.

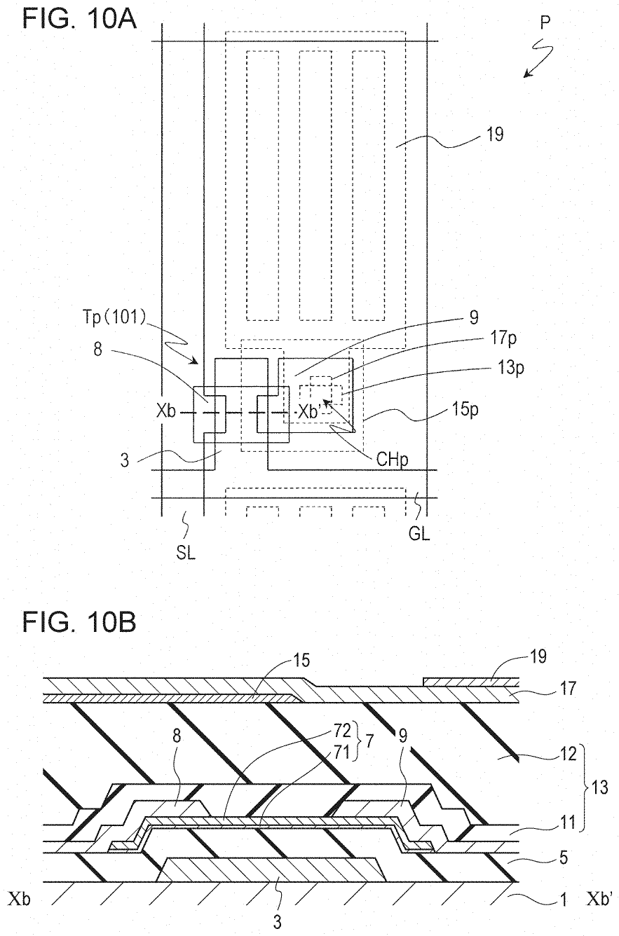

FIG. 10A is a plan view of a single pixel region P in the active matrix substrate 1000. FIG. 10B is a sectional view taken along line Xb-Xb′ in FIG. 10A.

The pixel region P is a region surrounded by the source bus line SL and the gate bus line GL extending in a direction orthogonal to the source bus line SL. The pixel region P includes the substrate 1, the thin film transistor (pixel TFT) Tp supported by the substrate 1, a lower transparent electrode 15, and an upper transparent electrode 19. In this example, the lower transparent electrode 15 is a common electrode CE, and the upper transparent electrode 19 is a pixel electrode PE. Alternatively, the lower transparent electrode 15 may be a pixel electrode PE, and the upper transparent electrode 19 may be a common electrode CE.

As the thin film transistor Tp, the TFTs 101 to 104 according to the first and the second embodiments can be used.

The gate electrode 3 of the thin film transistor Tp is connected to the corresponding gate bus line GL; the source electrode 8 of the thin film transistor Tp is connected to the corresponding source bus line SL. The drain electrode 9 is electrically connected to the pixel electrode PE. The gate electrode 3 and the gate bus line GL may be formed in one piece from the same conductive film. The source electrode 8, the drain electrode 9, and the source bus line SL may be formed in one piece from the same conductive film.

The interlayer insulating layer 13 is not particularly limited, but may include, for example, an inorganic insulating layer (passivation film) 11, and an organic insulating layer 12 disposed on the inorganic insulating layer 11. Incidentally, the interlayer insulating layer 13 may not necessarily include an organic insulating layer.

The pixel electrode PE and the common electrode CE are disposed so as to partially overlap with the dielectric layer 17 therebetween. The pixel electrode PE is divided for individual pixels. The common electrode CE may not be necessarily divided for individual pixels. In this example, the common electrode CE is formed on the interlayer insulating layer 13. The pixel electrode PE is formed on the dielectric layer 17, and is electrically connected through a contact hole CHp formed in the interlayer insulating layer 13 and the dielectric layer 17 to the drain electrode 9. In this example, a region shared by an opening 13p of the interlayer insulating layer 13 and an opening 17p of the dielectric layer 17 is the contact hole CHp. In each pixel, the pixel electrode PE may have at least one slit or notch (not shown). The common electrode CE has an opening 15p in a region in which a contact hole CH is formed. The common electrode CE may be formed over the whole pixel region P except for this region.

The pixel electrode PE and the common electrode CE may each be formed of, for example, an ITO (indium tin oxide) film, an In—Zn—O-based semiconductor (indium zinc oxide) film, or a ZnO film (zinc oxide film). The pixel electrode PE and the common electrode CE may each have a thickness of, for example, 50 nm or more and 200 nm or less. The dielectric layer 17 may be, for example, a silicon nitride (SiNx) film, a silicon oxide (SiOx) film, a silicon oxide nitride (SiOxNy; x>y) film, or a silicon nitride oxide (SiNxOy; x>y) film. The dielectric layer 17 may have a thickness of, for example, 70 nm or more and 300 nm or less.

Such an active matrix substrate 1000 is applicable to, for example, a display apparatus of an FFS mode. The FFS mode is a horizontal electric field mode in which, on one of substrates, a pair of electrodes (a pixel electrode PE and a common electrode CE) are disposed so as to apply, to liquid crystal molecules, an electric field in a direction (horizontal direction) parallel to the substrate surface.

The electrode structure in which the pixel electrode PE is disposed on the common electrode CE with the dielectric layer 17 therebetween is described in, for example, International Publication No. 2012/086513. The electrode structure in which the common electrode CE is disposed on the pixel electrode PE with the dielectric layer 17 therebetween is described in, for example, Japanese Unexamined Patent Application Publication No. 2008-032899 and Japanese Unexamined Patent Application Publication No. 2010-008758. For reference, the entire contents disclosed in International Publication No. 2012/086513, Japanese Unexamined Patent Application Publication No. 2008-032899, and Japanese Unexamined Patent Application Publication No. 2010-008758 are incorporated herein by reference.

In the active matrix substrate, the oxide semiconductor TFT can be used not only as a switching device disposed for each pixel, but also as a circuit device of a peripheral circuit such as a driver (in monolithic form). In such a case, the oxide semiconductor TFTs according to the first and second embodiments employ, as active layers, first oxide semiconductor layers having a high mobility (for example, 10 cm²/Vs or more), and hence are also suitably applicable as such circuit devices.

The above-described active matrix substrate is applicable to display apparatuses such as liquid crystal display apparatuses, organic electroluminescence (EL) display apparatuses, inorganic electroluminescence display apparatuses, and MEMS display apparatuses, image pickup devices such as image sensor devices, and various electronic apparatuses such as image input apparatuses, fingerprint reading apparatuses, and semiconductor memories.

1. A semiconductor device comprising a substrate and a thin film transistor supported by the substrate,
wherein the thin film transistor includes a semiconductor layer, a gate electrode, a gate insulating layer positioned between the semiconductor layer and the gate electrode, and a source electrode and a drain electrode that are electrically connected to the semiconductor layer,
the semiconductor layer has a stacked layer structure including
a first oxide semiconductor layer including In, Ga, Zn, and Sn, and
a second oxide semiconductor layer including In, Ga, Zn, and Sn, having a lower mobility than the first oxide semiconductor layer, and being disposed on the first oxide semiconductor layer so as to be in direct contact with the first oxide semiconductor layer,
the first oxide semiconductor layer and the second oxide semiconductor layer are amorphous, and
a Sn atomic ratio R1 relative to all metal elements in the first oxide semiconductor layer and a Sn atomic ratio R2 relative to all metal elements in the second oxide semiconductor layer satisfy
0.8×R1≤R2≤1.2×R1.

2. The semiconductor device according to claim 1, wherein the Sn atomic ratio R1 in the first oxide semiconductor layer and the Sn atomic ratio R2 in the second oxide semiconductor layer are each 5% or more and 25% or less.

3. The semiconductor device according to claim 1, wherein an In atomic ratio relative to all metal elements in the first oxide semiconductor layer is higher than an In atomic ratio relative to all metal elements in the second oxide semiconductor layer.

4. The semiconductor device according to claim 1, wherein, in the first oxide semiconductor layer, a Ga atomic ratio is lower than an In atomic ratio relative to all metal elements, and,
in the second oxide semiconductor layer, a Ga atomic ratio is higher than an In atomic ratio relative to all metal elements.

5. The semiconductor device according to claim 1, wherein, at a side surface of the semiconductor layer, a side surface of the first oxide semiconductor layer and a side surface of the second oxide semiconductor layer align in a thickness direction, and the side surface of the semiconductor layer has a non-stepped shape.

6. The semiconductor device according to claim 1, wherein the first oxide semiconductor layer and the second oxide semiconductor layer each include an In—Ga—Zn—Sn—O-based semiconductor.

7. The semiconductor device according to claim 6, wherein, in the first oxide semiconductor layer, relative to all metal elements, an In atomic ratio is 20% or more and 45% or less, a Ga atomic ratio is 5% or more and 20% or less, a Zn atomic ratio is 30% or more and 60% or less, and a Sn atomic ratio is 5% or more and 25% or less.

8. The semiconductor device according to claim 6, wherein, in the second oxide semiconductor layer, relative to all metal elements, an In atomic ratio is 10% or more and 20% or less, a Ga atomic ratio is 25% or more and 45% or less, a Zn atomic ratio is 20% or more and 35% or less, and a Sn atomic ratio is 5% or more and 25% or less.

9. The semiconductor device according to claim 1, wherein the gate electrode is positioned between the semiconductor layer and the substrate.

10. The semiconductor device according to claim 9, wherein the first oxide semiconductor layer has a thickness smaller than a thickness of the second oxide semiconductor layer.

11. The semiconductor device according to claim 1, wherein the gate electrode is positioned on a side of the semiconductor layer, the side being opposite from the substrate.

12. A method for producing a semiconductor device including a substrate and a thin film transistor supported by the substrate, the thin film transistor including a semiconductor layer, a gate electrode, a gate insulating layer formed between the gate electrode and the semiconductor layer, and a source electrode and a drain electrode that are electrically connected to the semiconductor layer, the semiconductor layer having a stacked layer structure including a first oxide semiconductor layer and a second oxide semiconductor layer,
the production method comprising:
Step (A) of forming a first oxide semiconductor film including In, Ga, Zn, and Sn and being amorphous;
Step (B) of forming, on the first oxide semiconductor film, a second oxide semiconductor film including In, Ga, Zn, and Sn, having a lower mobility than the first oxide semiconductor film, and being amorphous; and
Step (C) of patterning stacked semiconductor films including the first oxide semiconductor film and the second oxide semiconductor film to form, respectively from the first oxide semiconductor film and the second oxide semiconductor film, the first oxide semiconductor layer and the second oxide semiconductor layer,
wherein a Sn atomic ratio R1 relative to all metal elements in the first oxide semiconductor layer and a Sn atomic ratio R2 relative to all metal elements in the second oxide semiconductor layer satisfy
0.8×R1≤R2≤1.2×R1.

13. The method for producing a semiconductor device according to claim 12, wherein,
in the Step (C), wet etching using a PAN-based etchant being a mixture of phosphoric acid, nitric acid, and acetic acid is performed to pattern the first oxide semiconductor film and the second oxide semiconductor film,
a side surface of the semiconductor layer includes a side surface of the first oxide semiconductor layer and a side surface of the second oxide semiconductor layer, and
the side surface of the semiconductor layer has a non-stepped shape.
